(19) United States
(12) Patent Application Publication
(10) Pub. No.: US 2026/0186017 A1
(43) Pub. Date: Jul. 2, 2026

(54) SEMICONDUCTOR TESTING DEVICE AND INSPECTION SYSTEM

(71) Applicant: KABUSHIKI KAISHA NIHON MICRONICS, Tokyo (JP)

(72) Inventors: Hideki IKEUCHI, Musashino-shi (JP); Furawa ODAGIRI, Musashino-shi (JP); Shoujirou YAHATA, Musashino-shi (JP)

(73) Assignee: KABUSHIKI KAISHA NIHON MICRONICS, Tokyo (JP)

(21) Appl. No.: 19/412,549

(22) Filed: Dec. 8, 2025

(30) Foreign Application Priority Data
Dec. 26, 2024 (JP) 2024-231122

(51) Int. Cl. G01R 1/04; G01R 31/28

(52) U.S. Cl. CPC G01R 1/0416; G01R 31/2867

(57) ABSTRACT

A tester includes a plurality of slots which extend in a top-bottom direction provided, a card guide having a groove into which a side edge of circuit board units is inserted, a guide block located above the card guide, and overlaps a plurality of the card guides as seen from above and extends along an arrangement direction of the circuit board unit. The guide block exposes the groove for each of the card guides as seen from above, and has recesses for each card guide along with a circuit board unit temporary placement surface which is located between adjacent recesses as seen from above, and onto which the circuit board unit is temporarily placed provided.

### TECHNICAL FIELD

The present invention relates to a semiconductor testing device, and an inspection system. Priority is claimed on Japanese Patent Application No. 2024-231122, filed on December 26, 2024, the content of which is incorporated herein by reference.

### BACKGROUND ART

For example, a wafer test system that includes a test head and a prober is disclosed in Patent Document 1 (Japanese Unexamined Patent Application, First Publication No. 2004-172551). The wafer test system disclosed in Patent Document 1 includes the test head, and a test head support/reduction device.

### SUMMARY OF THE INVENTION

A wafer system such as the inspection system disclosed in Patent Document 1 includes a semiconductor testing device, such as the test head of Patent Document 1, which conducts inspection of a semiconductor integrated circuit. The semiconductor testing device includes a housing, and a plurality of circuit board units that are accommodated within the housing. When assembling the semiconductor testing device, each circuit board unit is inserted into each slot out of a plurality of slots provided inside the housing. Multiple types of the circuit board units exist, and the slots into which each of the circuit board units is to be inserted into is predetermined. Since the multiple slots are arranged close to one another, a risk of inserting the wrong circuit board unit into the wrong slot exists.

The present invention has been made in view of the above problem, and an object thereof is to suppress a circuit board unit from being inserted into the wrong slot, for a plurality of circuit board units on a semiconductor testing device accommodated with a housing.

As a means to solve the aforementioned problem, the present embodiment utilizes the following configuration.

A semiconductor testing device according to an embodiment of the present invention includes a housing which has a plurality of slots, where each of the slot accommodates a circuit board unit, a plurality of the circuit board units that are arranged so as to face one another in a horizontal direction, and are placed inside the housing by having each circuit board unit inserted from above into each of the slots, guide members provided so as to extend in a top-bottom direction of each of the slots, each having grooves through which side edges of each of the circuit board units is inserted, and a block member, which is located above each of the guide members, and is provided so as to extend along an arrangement direction of each of the circuit board units so as to overlap with the plurality of guide members as seen from above. The block member exposes the groove for each guide member as seen from above, and has recesses for each guide member along with a circuit board unit temporary placement surface which is located between adjacent recesses as seen from above, and onto which the circuit board unit is temporarily placed provided.

An inspection system according to an embodiment of the present invention may include the aforementioned semiconductor testing device, and a test object transport device that transports the test object which has a semiconductor integrated circuit provided thereon, and is connected to the semiconductor testing device.

According to the present invention, it is possible to suppress a circuit board unit from being inserted into the wrong slot, for a plurality of circuit board units on a semiconductor testing device accommodated within a housing.

### BRIEF DESCRIPTION OF DRAWINGS

FIG. 1 A schematic diagram showing an outline configuration of an inspection system in an embodiment of the present invention.

FIG. 2 A perspective view of a tester in an embodiment of the present invention.

FIG. 3 An exploded perspective view of the tester in an embodiment of the present invention.

FIG. 4 A front view of a circuit board unit seen from a horizontal direction in an embodiment of the present invention.

FIG. 5 A schematic plan view of a main body housing seen from above in an embodiment of the present invention.

FIG. 6 A schematic front view of a card guide seen from a Y-direction in an embodiment of the present invention.

FIG. 7 An exploded view of portion A of FIG. 6.

FIG. 8 A schematic perspective view of a circuit board unit when being inserted into a slot in an embodiment of the present invention.

FIG. 9 A plan view of a schematic part of a guide block included in a modification example of the tester of the present invention.

### DESCRIPTION OF EMBODIMENTS

Hereinafter, an embodiment of a semiconductor testing device and an inspection system according to the present invention is described with reference to the drawings.

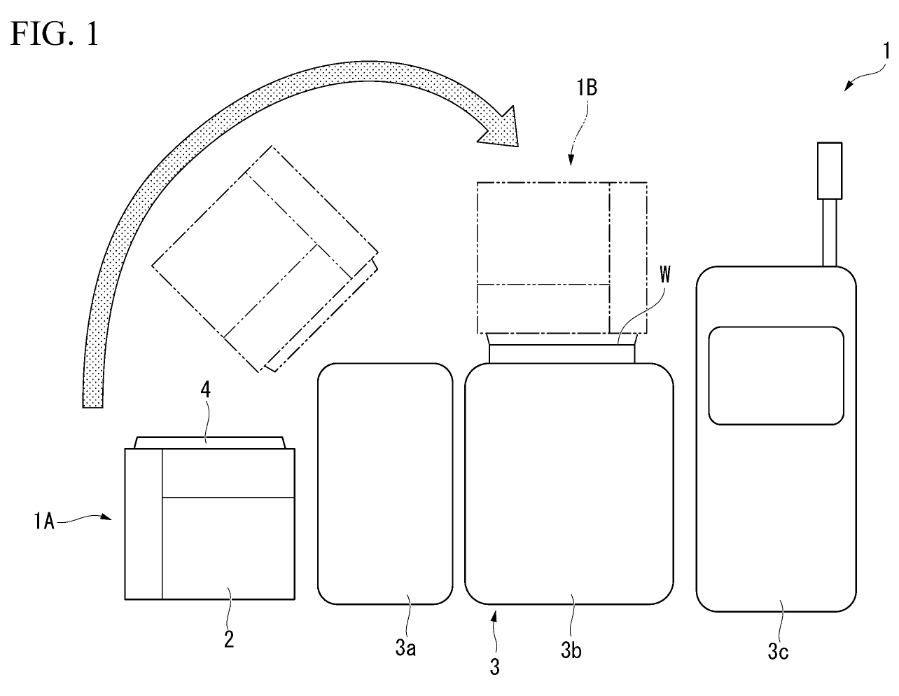

FIG. 1 is a schematic diagram showing an outline configuration of an inspection system 1 of the present embodiment. The inspection system 1 of the present embodiment conducts inspection of electrical characteristics of a semiconductor integrated circuit, where a wafer W having a semiconductor circuit is provided as a test object. As shown in FIG. 1, the inspection system 1 includes a tester 2 (semiconductor testing device), and a prober 3 (test object transport device). The aforementioned inspection system 1 inspects electrical characteristics of each semiconductor circuit before a plurality of semiconductor circuits which are formed on the wafer W are individually diced into chips.

A probe card 4 is installed in the tester 2. The probe card 4 includes a plurality of probes. The prober 3 causes the probe card 4, having the plurality of probes provided thereon, to contact pads of the plurality of the semiconductor circuits that are formed on the wafer W. The prober 3 includes a tester transport device 3a, a stage device 3b, and a wafer transport device 3c.

The tester transport device 3a includes a transport mechanism that is not shown on the drawings, and moves the tester 2 from the standby position 1A to the inspection position 1B. The stage device 3b supports the wafer W, and aligns a location of the tester 2 and the wafer W located at the inspection position 1B. The stage device 3b is movable in a planar direction along a horizontal plane, and in a vertical direction that is perpendicular to the horizontal plane. The stage device 3b is rotatable around the vertical axis in the θ-direction. The wafer transport device 3c transports the wafer W on the stage device 3b.

When conducting inspection, the stage device 3b moves the wafer W, and causes the pads of the plurality of semiconductors, which are formed on the wafer W to contact tips of the plurality of probes of the probe card 4 provided in the tester 2 which is located in the inspection position 1B. In such state, the tester 2 inputs a test signal simultaneously to each semiconductor circuit via each of the plurality of probes, and by receiving the input signal from each semiconductor circuit, inspects of each semiconductor circuits.

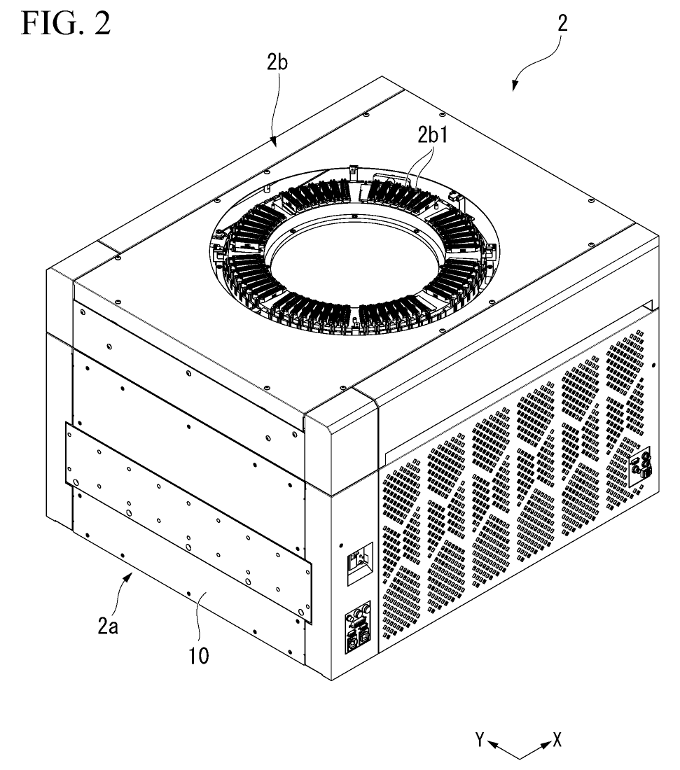

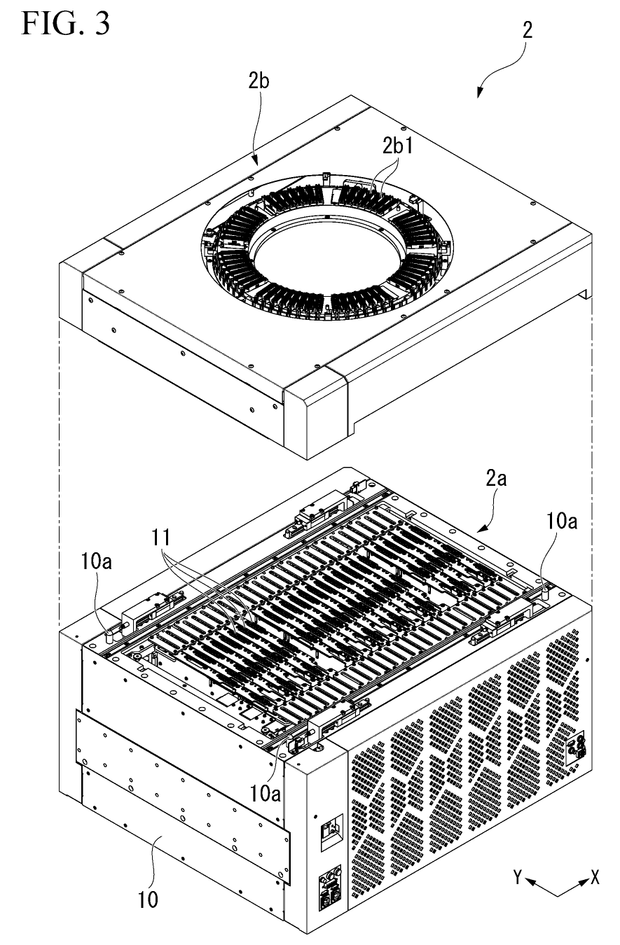

FIG. 2 is a perspective view of the tester 2. FIG. 3 is an exploded perspective view of the tester 2. As shown in these figures, the tester 2 includes a main body 2a, and a performance board unit 2b. In FIGS. 2 and 3, the tester 2 being disposed in the standby position 1A is shown. The tester 2 in the standby position 1A is oriented so as to face above on the side the probe card 4 is installed on. In the explanations hereinafter, explanations are carried out based on a direction where the tester 2 is in a state of being disposed in the standby position 1A. In the present embodiment, a circuit board unit 11 to be mentioned later on has a plurality of arrays disposed so as to face one another in the horizontal direction, and in the explanations below, an arrangement direction of the plurality of circuit board units 11 is an X-direction. A direction that is orthogonal to the X-direction is a Y-direction.

The main body 2a is a unit that conducts signal processing for testing of the wafer W, and detachably supports the performance board unit 2b. The main body 2a includes a main body housing 10 (housing), and a plurality of circuit board units 11. The main body 2a also include a control processing unit not shown on the drawings. The control processing unit for example, inputs control signals to the circuit board unit 11. The control processing unit may also process signals from each of the circuit board units 11. A battery may also be accommodated inside the main body housing 10, and the processing control unit may include a power unit for distributing power from the battery to each of the circuit board units 11 and so on.

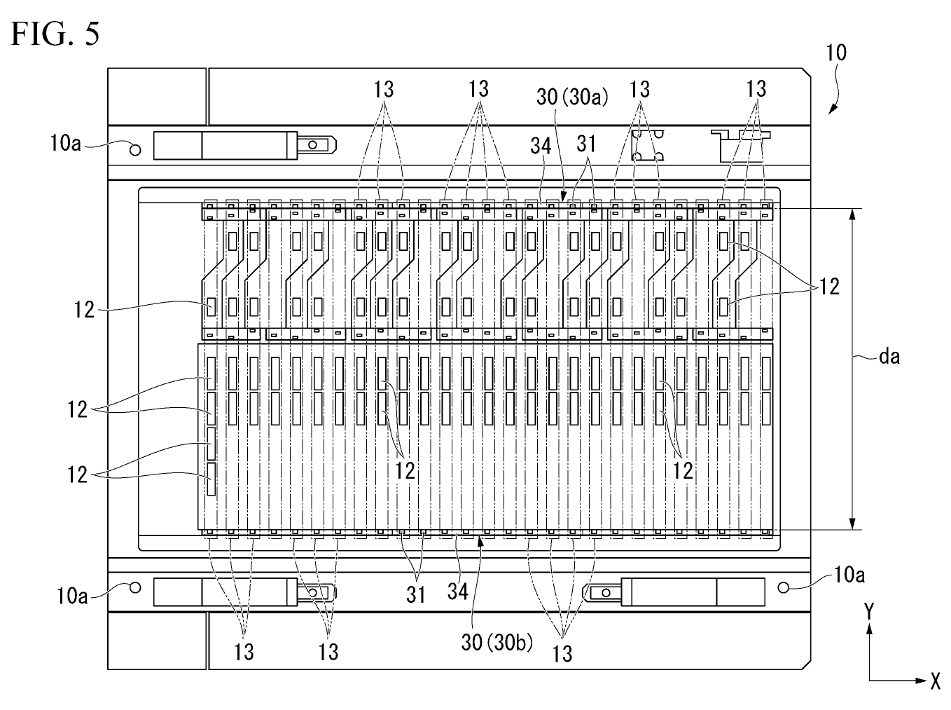

The main body housing 10 is a housing in which the circuit board units 11 are housed. In the present embodiment, the main body housing 10 is formed as a box shape having an opening that faces above. A plurality of slots 13 (refer to FIG. 5) into which the circuit boards 11 are insertable, are provided inside the main body housing 10. The circuit board units 11 are accommodated within the main body housing 10 by inserting each of the circuit board units 11 into the slots 13. A plurality of location pins 10a for determining a position of the performance board unit are provided on an upper surface of the main body housing 10. The aforementioned location pins 10a of the performance board unit determine a horizontal position of the performance board unit 2b, in a case where the performance board unit 2b is installed to the main body 2a from above.

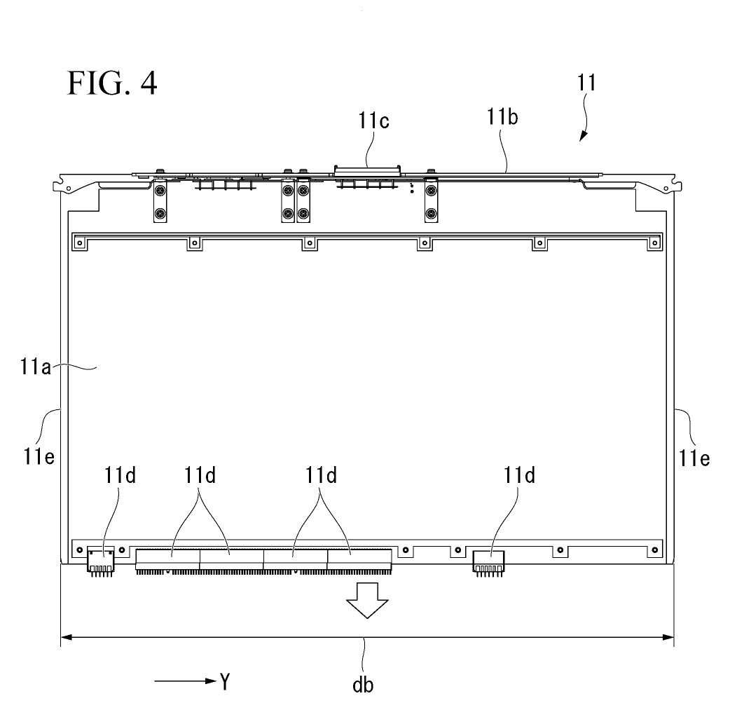

The circuit board units 11 is a circuit board onto which various electronic components that conduct various signal processes are mounted, and is exchangeable according to the type of test to be conducted on the wafer W. FIG. 4 is a front view of the circuit board unit 11 seen from a horizontal direction. As shown on FIG. 4, the circuit board unit 11 includes a circuit board main body 11a, an upper plate 11b, an upper connector 11c, and a lower connector 11d.

The circuit board main body 11a is an electronic circuit board that is accommodated inside the main body housing 10 so that front and back surfaces thereof face the horizontal direction. As shown in FIG. 3, the plurality of the circuit board units 11 are arranged so as to have the front back surfaces of circuit board main bodies 11a face one another in the X-direction. The aforementioned X-direction is the horizontal direction when the tester 2 is located in the standby position 1A. In other words, the circuit board unit 11 includes the circuit board main body 11a which is inserted into the main body housing 10 having an orientation of the front back surface thereof face the X-direction along the horizontal direction. Each side edge of the aforementioned circuit board main body 11a forms a side edge 11e of the circuit board unit 11.

Each upper plate 11b is a band shaped plate member to which top edges of each of the circuit board units 11a are connected to. The upper plates 11b extends along the Y-direction in a plan view. Each of the upper plates 11b has the upper connector 11c fixed thereto. The upper plate 11b may be formed as a single band shaped plate member, and may be formed from a plurality of stacked plate members.

Upper connectors 11c are provided for each circuit board main body 11a. For example, each circuit board main body 11a may have one to three upper connectors 11c provided. Each of the upper connectors 11c is fixed to the upper plate 11b, and is electrically connected to the circuit board main body 11a. As such, the upper connector 11c is connectable to a lower connector of a performance board unit to be mentioned later on, which is included in the performance board unit 2b. By having the upper connector 11c connected to the lower connector of the performance board unit, the circuit board unit 11 is electrically connected to the performance board unit 2b.

The lower connector 11d is provided on a lower end edge of each circuit board main body 11a. A plurality of bottom connectors 12 (refer to FIG. 5) are provided on a bottom of the inside of the main body housing 10. Each of the lower connectors 11d is connected to each bottom connector 12. For example, by having the circuit board unit 11 be connected to the bottom connector 12, the circuit board unit 11 is electrically connected to the processing control unit. It is possible to change a number of the installed lower connectors 11d so as to the circuit board units 11.

By inserting the circuit board main body 11a through the slot 13 provided in the main body housing 10, each circuit board unit 11 is accommodated inside the main body housing 10. Each circuit board unit 11 is inserted into the main body housing 10 from above, towards the bottom as shown by the arrow in FIG. 4. Differing types of the circuit board units 11 for example, may exist depending on differing functions or the like. In other words, the differing types of circuit board units 11 are accommodated in the main body housing 10. The aforementioned differing types of circuit board units 11 may be installed at predetermined locations inside the main body housing 10, according to types thereof.

FIG. 5 is a schematic plan view of the main body housing 10 seen from above. As shown in FIG. 5, the slots 13, into which the circuit board units 11 are insertable, are provided in the main body housing 10. The slots 13 are provided for each type of the circuit board unit 11, and are arranged in the X-direction. The aforementioned bottom connector 12 is provided in one of the slots 13.

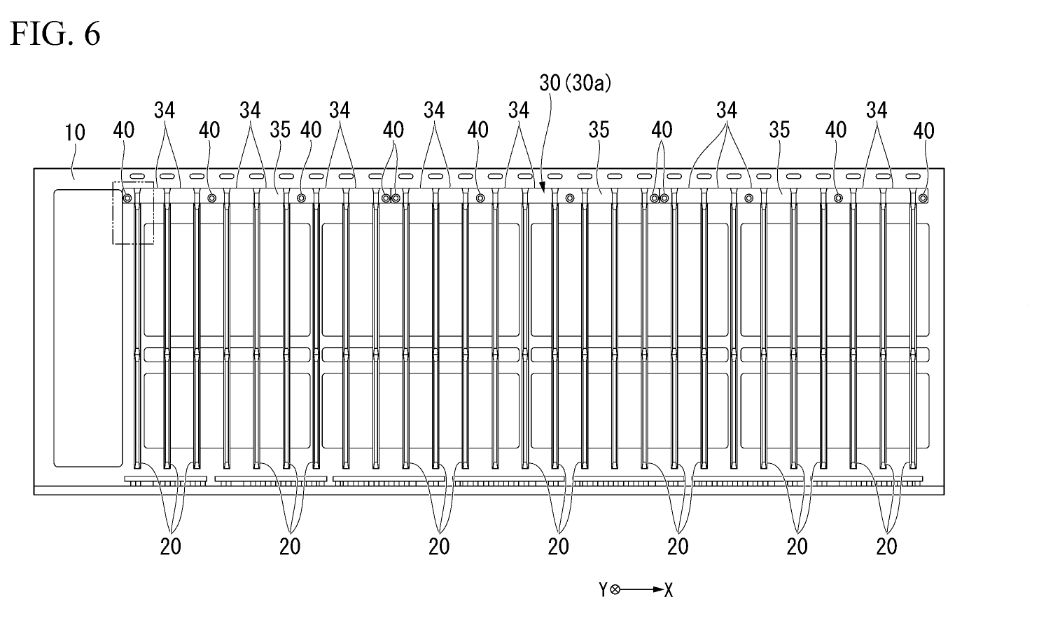

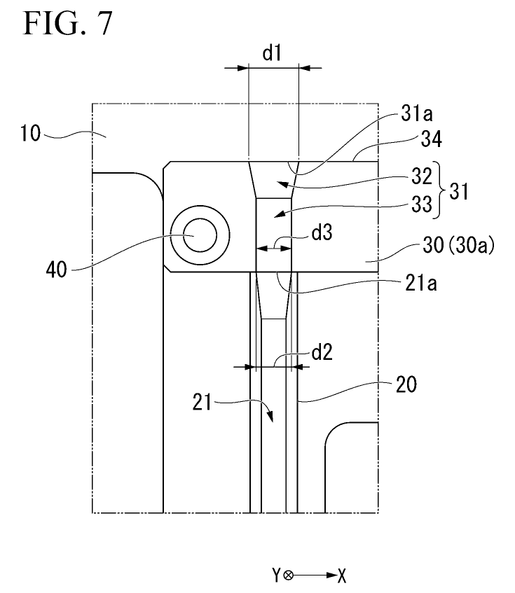

Each of the slots 13 is provided so as to extend in the Y-direction (slot extension direction), as shown in FIG. 5. The card guide 20 (guide member) is provided on both ends of each slot 13 in the Y-direction. FIG. 6 is a schematic front view of a card guide 20 seen from the Y-direction. FIG. 7 is an exploded view of portion A of FIG. 6. As shown in FIGS. 6 and 7, a guide block 30 (block member) is provided above the card guide 20. In other words the tester 2 according to the present embodiment includes a plurality of card guides 20, and a plurality of guide blocks 30.

As mentioned above, the card guide 20 is located on both ends of each slot 13 in the Y-direction. In other words, two of the card guides 20 are provided for every slot 13. In FIG. 6, the card guide 20 located on an end in a first side of the slot 13 of one card guide 20 out of the two provided card guides 20 is shown. Since the card guide 20 located on an end in a second side of the slot 13 of one card guide 20 out of the two provided card guides 20 has the same structure as the card guide 20 located on the end in the first side, explanations thereof are omitted.

As shown in FIG. 6, each card guide 20 is provided so as to extend in a top-bottom direction in each slot 13. A groove 21 into which the side edge 11e of the circuit board unit 11 is inserted into is provided on each card guide 20. The groove 21 is formed so as to recess from the inside of the main body housing 10 to the outside along the Y-direction. An upper end of the groove 21 opens above. As such, for the groove 21, in a case where the circuit board unit 11 is being inserted into the slot 13, an entrance of the upper end of the groove 21 is an entrance edge 21a. The groove 21 has a width dimension (X-direction dimension) that continuously decreases towards the bottom from the entrance edge 21a, and becomes a constant width dimension after the lower connector 11d of the circuit board unit 11 which is inserted into the groove 21 is aligned so as to be in a location where it is possible to mate with the bottom connector 12.

The main body housing 10 is fixed to the above card guide 20. For example, the main body housing 10 includes a frame that is not shown on the drawings, and the card guide 20 is fixed to the frame. Each of the card guides 20 may be divided and formed as a plurality of parts that arranged in the top-bottom direction.

The guide block 30 is provided above each of the card guide 20 located on the end in the first side of the slot 13 and the card guide 20 located on the end in the second side of the slot 13. In other words, the same number of the card guides 20 located on the end in the first side of the slot 13 as the number of the slots 13 are provided, and are aligned in the X-direction. One of the guide blocks 30 is provided above the aforementioned card guides 20. The same number of card guides 20 located on the end in the second side of the slot 13 as the number of the slots 13 are provided, and are aligned in the X-direction. Similarly, one of the guide blocks 30 is provided above the aforementioned card guides 20.

The guide block 30 above the card guide 20 located on the end in the first side of the slot 13 is referred to as a “first guide block 30a”, and the guide block 30 above the card guide 20 located on the end in the second side of the slot 13 is referred to as a “second guide block 30b”. In other words, as the guide block 30, the tester 2 has the first guide block 30a, which is the guide block 30 located on the end in the first side of the slot 13 in the Y-direction as seen from above, and the second guide block 30b, which is the guide block 30 located on the end in the second side of the slot 13 in the Y-direction as seen from above.

As shown in FIG. 5, each of the guide blocks 30 is a rod member that extends along the X-direction. In the present embodiment, the guide block 30 is formed having a rectangular cross-section. Each of the guide blocks 30 is disposed so as to overlap with the plurality of card guides 20, as seen from above. Specifically, the first guide block 30a is disposed so as to overlap with the card guide 20 located on the end in the first side of the slot 13. The second guide block 30b is disposed so as to overlap with the card guide 20 located on the end in the second side of the slog 13.

As seen from above, each guide block 30 includes a recess 31 provided so as to expose the groove 21 of the card guide 20, for each card guide 20. As with the groove 21 of the card guide 20, the recess 31 is formed so as to recess from the inside of the main body housing 10 to the outside along the Y-direction. The recess 31 is formed so as to penetrate the guide block 30 from top to bottom. A top end of the recess 31 is an entrance edge 31a, which is an entrance of the recess 31 in a case where the circuit board unit 11 is inserted into the slot 13.

As shown in FIG. 7, an upper location 32 which forms a top of the recess 31 and a lower location 33 which forms a bottom of the recess 31 are provided as part of each recess 31. Along with having the entrance edge 31a provided, the upper location 32 is formed having a width dimension (X-direction dimension) that continuously decreases towards the bottom. Along with being connected to a bottom end of the upper location 32, the lower location 33 is formed so as to connect to the entrance edge 21a of the groove 21.

A width dimension d1 (X-direction dimension) of the entrance edge 31a of the recess 31 is larger than a width dimension d2 of the entrance edge 21a of the groove 21. It is preferable to have a width dimension d3 at the lower end of the lower location 33 be less than or equal to the width dimension d2 of the entrance edge 21a of the groove 21. By having the width dimension d3 at the lower end of the lower location 33 be less than or equal to the width dimension d2 of the entrance edge 21a of the groove 21, it is possible to prevent the circuit board unit 11 from hooking onto the card guide 20 when the circuit board unit 11 is being inserted thereto.

A circuit board unit temporary placement surface 34 onto which it is possible to temporarily place the circuit board unit 11 is provided between the recess 31 and the recess 31 of the guide block 30. In other words, the guide block 30 has a circuit board unit temporary placement surface 34 provided between two recesses 31. The circuit board unit temporary placement surface 34 is formed using an upper surface of the guide block 30.

As shown in FIG. 5, a separation dimension da between the circuit board unit temporary placement surface 34 of the first guide block 30a and the circuit board unit temporary placement surface 34 of the second guide block 30b is smaller than a length dimension db (refer to FIG. 4) of the circuit board unit 11 in the Y-direction. As such, it is possible to have both ends of the circuit board unit 11 be temporarily placed on the circuit board unit temporary placement surface 34 of the guide block 30, before inserting the circuit board unit 11 into the slot 13.

As shown in FIG. 6, each of the guide blocks 30 is fixed to the main body housing 10 using bolts 40. Each of the guide blocks 30 may be divided and formed as a plurality of parts 35 that are arranged in the X-direction.

Returning back to FIGS. 2 and 3, the performance board unit 2b is detachable with respect to the main body 2a, and is fixed to the main body 2a via a locking mechanism not shown on the drawings. The performance board unit 2b is connected to the probe card 4 from above, and is electrically connectable to the probe card 4 via the wafer W.

The aforementioned performance board unit 2b includes a plurality of lower connectors for the performance board unit which are connected to the upper connector 11c of the circuit board unit 11, and are not shown on the drawings. The performance board unit 2b also includes a plurality of upper connectors 2b1 for the performance board unit which are connected to the probe card 4, as shown in FIG. 2 and in FIG. 3.

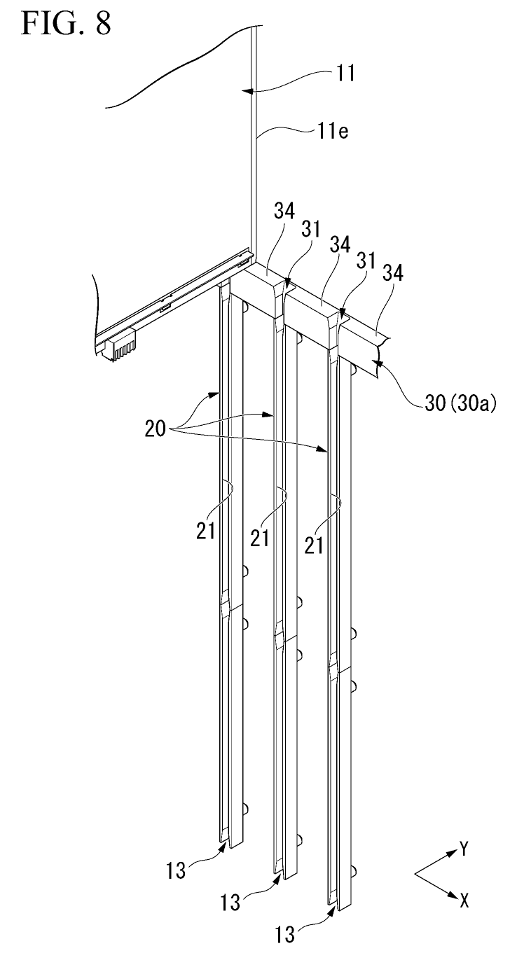

In such an assembly of the tester 2, the circuit board units 11 are inserted into each slot 13 of the main body housing 10. FIG. 8 is a schematic perspective view of the circuit board unit 11 when being inserted into the slot 13. As shown on the drawing, an operator has both ends of the circuit board unit 11 contact the circuit board unit temporary placement surface 34 of the guide block 30 from above, making it is possible to temporarily place the circuit board unit 11 on the guide block 30. As such, in a state where the circuit board unit 11 is temporarily placed, it is possible to visually and so on confirm the slot 13 into which the circuit board unit 11 is to be inserted into.

Next, the side edge 11e of the circuit board unit 11 is aligned with the recess 31 of the guide block 30, and the circuit board unit 11 is inserted from above towards the bottom. The side edge 11e of the circuit board unit 11 is inserted to the groove 21 of the card guide 20, and is inserted to the lowest point in the slot 13 while being guided by the card guide 20. Once insertion of all the circuit board units 11 into all of the slots 13 is complete, the performance board unit 2b is fixed to the main body 2a, and assembly of the tester 2 is complete.

The tester 2 in the aforementioned present embodiment includes the main body housing 10, the plurality of control board units 11, the card guides 20, and the guide blocks 30. The main body housing 10 has a plurality of the slots 13 into which the control board units 11 are inserted therein provided. The control board unit 11 is inserted into the slot 13 from above, and is set inside the main body housing 10. The plurality of the circuit board units 11 are horizontally arranged with respect to one another. The card guide 20 is provided so as to extend in the top-bottom direction within each slot 13. The card guide 20 has the groove 21 which the side edge 11e of the circuit board unit 11 is inserted into provided. The guide block 30 is located above the card guide 20, and is provided so overlap the plurality of the card guides 20 when seen from above, and to extend along the arrangement direction (X-direction) of the circuit board units 11.

The guide block 30 has the recess 31 and the circuit board unit temporary placement surface 34 provided. The recess 31 exposes the groove 21 of the card guide 20 when seen from above. The recess 31 is provided for each card guide 20. It is possible to temporarily place the circuit board unit 11 on the circuit board unit temporary placement surface 34 between the recesses 31 that are adjacent to one another when seen from above.

According to the tester 2 of the aforementioned present embodiment, when assembling the tester 2, both ends of the circuit board unit 11 contact the circuit board unit temporary placement surface 34 of the guide block 30, and the circuit board unit 11 is temporarily placed on the guide block 30 before the operator inserts the circuit board unit 11 into the slot 13. As such, when the circuit board unit 11 is in a state of temporary placement, it is possible to visually and so on confirm whether or not the circuit board unit 11 will be inserted in the correct slot 13. In a state where the circuit board unit 11 is in temporary placement, it is also possible to change the orientation of the circuit board unit 11. Therefore, compared to a case where temporarily placement of the circuit board unit 11 before insertion into the slot 13 is not possible, reducing the possibility of having the wrong circuit board unit 11 from being inserted into the wrong slot 13 is possible. Therefore, according to the tester 2 of the present embodiment, it is possible to suppress having the wrong circuit board unit 11 from being inserted into the wrong slot 13, for the plurality of circuit board units 11 accommodated inside the main body housing 10 in the tester 2.

According to the tester 2 of the present embodiment, the card guide 20 is provided on each of both ends in the extension direction (Y-direction) of each slot, i.e. a direction that is normal to the arrangement direction of the slots 13. As the guide block 30 the first guide block 30a and the second guide block 30b are provided. The first guide block 30a is the guide block 30 that is located on the end in the first side of the slot 13 in the Y-direction, as seen from above. The second guide block 30b is the guide block 30 that is located on the end in the second side of the slot 13 in the Y-direction, as seen from above. The separation dimension da between the circuit board unit temporary placement surface 34 of the first guide block 30a and the circuit board unit temporary placement surface 34 of the second guide block 30b is smaller than the length dimension db of the circuit board unit 11 in the Y-direction.

According to the tester 2 of the above present invention, when there is temporary placement of the circuit board unit 11 on the circuit board unit temporary placement surface 34, it is possible to have both ends of the circuit board 11 be temporarily placed on each of the guide blocks 30. In other words, when the circuit board unit 11 is temporarily placed on the circuit board unit temporary placement surface 34, the circuit board unit 11 is temporarily placed so as to straddles the first guide block 30a and the second guide block 30b. Therefore, according to the tester 2 of the present embodiment, compared to a case where only one of the two ends of the circuit board unit 11 is temporarily placed on the guide block 30, it is possible to cause the circuit board unit 11 to stabilize more.

In the tester 2 of the present embodiment, the guide block 30 may be divided and formed into the plurality of parts 35 that are arranged in the X-direction. By dividing and forming the guide block 30, handling thereof during manufacturing is easier, in contrast to the guide block 30 which is not divided and formed.

In the tester 2 of the present embodiment, the width dimension d1 of the entrance edge 31a of the recess 31 is larger than the width dimension d2 of the entrance edge 21a of the groove 21. According to the tester 2 of the present embodiment, it is possible to insert the circuit board unit 11 into the groove 21 of the card guide 20, via the recess 31 having a large width dimension d1 of the entrance edge 31a. Accordingly, compared to when the guide block 30 is not provided, it is easier to insert the circuit board unit 11 into the groove 21 of the card guide 20.

The recess 31 in the tester 2 of the present embodiment has the upper location 32 and the lower location 33 provided. The upper location 32 has the entrance edge 31a, and the width dimension of the upper location 32 continuously decreases towards the bottom. Along with being connected to the lower end of the upper location 32, the lower location 33 is connected to the entrance edge 21a of the groove 21. According to the tester 2 of the aforementioned present embodiment, it is possible to determine the position of the circuit board unit 11 in the X-direction that moves towards the bottom from above, and it is possible to easily insert the circuit board unit 11 into the groove 21 of the card guide 20.

In the tester 2 of the present embodiment, the width dimension d3 at the lower end of the lower location 33 is less than or equal to the width dimension d2 of the entrance edge 21a of the groove 21. According to the tester 2 of the aforementioned present embodiment, it is possible to prevent a top end surface of the card guide 20 from being exposed to the recess 31, and it is possible to easily insert the circuit board unit 11 through the groove 21 of the card guide 20.

The inspection system 1 of the present embodiment includes the tester 2, and the prober 3. The prober 3 causes the wafer W which has the semiconductor integrated circuit provided thereon move and contact the tester 2. According to the inspection system 1 of the aforementioned present embodiment, since the inspection system 1 includes the tester 2, it is possible to suppress having the wrong circuit board unit 11 from being inserted into the wrong slot 13.

Although a preferable embodiment of the present invention is explained above, the embodiment serves as an example, and the present invention should not be construed as being limited to the embodiment herein. Additions, omissions, exchanging of components or other changes may be made so long as they are within the technical scope of the present invention. Therefore, the present invention is not limited to the aforementioned embodiment, but rather by the technical scope of the present invention.

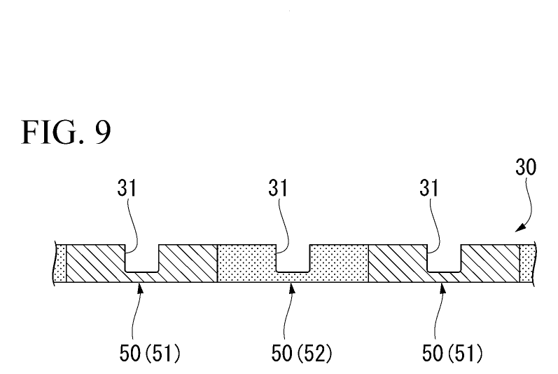

For example, as shown in FIG. 9, the guide block 30 is divided into a plurality of the recesses 31, and each divided region 50 may be separated by two consecutive different colors. In other words, in a case where black and white are used to color separate the region 50, a black colored region 50 (black region 51), and a white colored region 50 (white region 52) are consecutively aligned along the extension direction of the guide block 30. As such, it becomes easier to identify the adjacent recess 31, and it is possible to further suppress having the wrong circuit board unit 11 be inserted into the wrong slot 13. It is preferable for the first guide block 30a and the second guide block 30b that are within the same region 50 included in the same slot 13 to have the same color. As such, since it is possible to insert both ends of the circuit board unit 11 into the recess 31 of the region 50 having the same color, it is possible to further suppress the wrong circuit board unit 11 from being inserted into the wrong slot 13.

In the aforementioned embodiment, the circuit board unit temporary placement surface 34 of the guide block 30 may be made to have a high friction surface. Doing so would make it possible to suppress the circuit board unit 11 from slipping when being temporarily placed on the circuit board unit temporary placement surface 34. To increase friction, surface roughness of the circuit board unit temporary placement surface 34 may be rougher than other surfaces of the guide block 30. To increase friction for example, coating material on the circuit board unit temporary placement surface 34 may be used.

The shape of the tester 2 for example, is not limited to the shape shown in the drawings of the aforementioned embodiments. The shape of the tester 2 for example, may be a shape that is smaller than what is shown in the drawings.

In the aforementioned embodiment, an example where an inspection system using the prober 3 as a test object transport device is explained. However, the present invention is not limited thereto. For example, an inspection system where a handler is used as the test object transport device may be applied to the present invention. When using the inspection system that includes the handler for the present invention, the handler moves with respect to the tester 2, and the tester 2 connects to the wafer W via a probe card.

The test object is not limited to a wafer. For example, the test object may be a device that is packaged. In such case, the tester 2 contacts the device via a test socket.

Although embodiments of the present invention have been described above in detail with reference to the drawings, specific configurations are not limited to the embodiments and other designs and the like may also be included without departing from the objective and scope of the present invention.

What is claimed is:

1. A semiconductor testing device comprising:
a housing which has a plurality of slots;
a plurality of circuit board units that are arranged so as to face one another in a horizontal direction, and are placed inside the housing by having each circuit board unit inserted from above into each of the slots;
a guide member provided so as to extend in a top-bottom direction in each of the slots, having grooves through which side edges of each of the circuit board units is inserted; and
a block member, which is located above each of the guide members, and is provided so as to extend along an arrangement direction of each of the circuit board units so as to overlap with the plurality of guide members as seen from above;
wherein the block member is provided with:
recesses that expose the grooves of the guide members as seen from above, and are provided for each of the guide members, and
a circuit board unit temporary placement surface located between each of the recesses that are adjacent to one another as seen from above, and onto which it is possible to temporarily place the circuit board units.

2. The semiconductor testing device according to claim 1, wherein
each of the guide members is provided on both ends of each of the slots in the horizontal direction perpendicular to the arrangement direction, which is an extension direction of the slots,
a first block member which is the block member that is located on a first side of the slot in the extension direction of the slots as seen from above, and a second block member which is the block member that is located on a second side of the slot in the extension direction of the slots as seen from above are provided in the block member, and
a separation dimension between the circuit board unit temporary placement surface of the first block member and the circuit board unit temporary placement surface of the second block member is smaller than a length dimension of the circuit board unit in the extension direction of the slots.

3. The semiconductor testing device according to claim 1, wherein
the block member is divided and formed as a plurality of parts that are arranged in the arrangement direction.

4. The semiconductor testing device according to claim 1, wherein
a dimension of an entrance edge of each of the recesses in the arrangement direction is larger than a dimension of an entrance edge of each of the grooves in the arrangement direction.

5. The semiconductor testing device according to claim 4, wherein
each of the recesses includes
an upper location having an entrance edge provided, and is formed having a width dimension that continuously decreases towards the bottom, and
a lower location which is connected to a bottom end of the upper location, and is formed so as to connect to the entrance edge of the groove.

6. The semiconductor testing device according to claim 5, wherein
a width dimension of a bottom end of the bottom location is less than or equal to the width dimension of the entrance edge of the groove.

7. The semiconductor testing device according to claim 1, wherein
the block member has each of the plurality of recesses separated using different colors.

8. An inspection system comprising:
the semiconductor testing device according to claim 1; and
a test object transport device that transports a test object which has a semiconductor integrated circuit provided thereon, and connects the test object to the semiconductor testing device.
